(19) United States
(12) Patent Application Publication
(10) Pub. No.: US 2024/0282716 A1
(43) Pub. Date: Aug. 22, 2024

(54) STRUCTURE AND METHOD FOR BONDED WAFER BARRIER

(71) Applicant: TEXAS INSTRUMENTS INCORPORATED, Dallas, TX (US)

(72) Inventors: John C. Ehmke, Longview, TX (US); Jennifer Lynne Holm, Dallas, TX (US)

(21) Appl. No.: 18/141,265

(22) Filed: Apr. 28, 2023

Related U.S. Application Data
(60) Provisional application No. 63/485,300, filed on Feb. 16, 2023.

(51) Int. Cl. H01L 23/00; B81B 7/00

(52) U.S. Cl. CPC H01L 23/562; B81B 7/008; H01L 24/06; H01L 2224/06135

(57) ABSTRACT

An example apparatus includes a semiconductor device layer including a bond pad area, a bond pad on the semiconductor device layer in the bond pad area; a scribe seal on the semiconductor device layer, the scribe seal surrounding the bond pad on at least three sides; and a swarf barrier on the scribe seal, the swarf barrier including: a first portion a first distance from the semiconductor device layer; and a second portion a second distance from the semiconductor device layer, the second distance being larger than the first distance.

### CROSS-REFERENCE TO RELATED APPLICATION

This patent application claims the benefit of and priority to U.S. Provisional Patent Application Ser. No. 62/485,300 filed Feb. 16, 2023, which Application is hereby incorporated herein by reference in its entirety.

### TECHNICAL FIELD

This description relates generally to semiconductors, and more particularly, to a structure and method for bonded wafer barrier.

### BACKGROUND

A bonded wafer is a packaging technology in which different layers of material are bonded together. The layers may include a glass layer, an interposer layer, and a semiconductor layer. The semiconductor layer includes semiconductor components that are structured to make integrated circuits. Thus, a bonded wafer includes a plurality of integrated circuits. After the bonded wafer is created, the bonded wafer is cut to separate the plurality of integrated circuits into separate components.

### SUMMARY

For a structure and method for bonded wafer barrier, an example apparatus includes a first layer corresponding to a semiconductor device, the first layer including an area including a bond pad; a scribe seal on the first layer, the scribe seal including a portion of the scribe seal that surrounds the bond pad on at least three sides; and a metal barrier on top of the portion of the scribe seal, the metal barrier including: a first portion located a first distance away from the first layer; and a second portion located a second distance away from the first layer, the second distance being larger than the first distance, the second portion structured to contact a second layer on top of the first layer.

### BRIEF DESCRIPTION OF THE DRAWINGS

FIGS. 1A-1C illustrate a schematic diagram of a bonded wafer.

FIG. 2 illustrates an over-the-top view of a portion of a bonded wafer described in conjunction with examples disclosed herein.

FIGS. 3A-3B illustrate cross-sectional views of a portion of the bonded wafer of FIG. 2.

FIG. 4 illustrates an isometric view of a portion of the bonded wafer of FIG. 2.

FIGS. 5A and 5B illustrate an isometric view and an orthogonal of an example barrier finger of FIG. 2.

FIGS. 6A-6B illustrate cross-sectional views of a portion of the bonded wafer of FIG. 2 before and after removal of a portion of a glass window and/or silicon interposer.

FIGS. 7A-7B illustrate cross-sectional views of another portion of a bonded wafer during and after removal of a portion of a glass window and/or silicon interposer.

FIG. 8 is a flowchart representative of instructions and/or operations to implement the generate the bonded wafer of FIGS. 2-7B.

The same reference numbers or other reference designators are used in the drawings to designate the same or similar (functionally and/or structurally) features.

### DETAILED DESCRIPTION

The drawings are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular. Generally, the same reference numbers in the drawing(s) and this description refer to the same or like parts. Although the drawings show regions with clean lines and boundaries, some or all of these lines and/or boundaries may be idealized. In reality, the boundaries and/or lines may be unobservable, blended and/or irregular.

A bonded wafer is used to generate microelectromechanical system (MEMS) devices, nanoelectromechanical system (NEMS) devices, microelectronics, mirror applications, etc. One example of a MEMS device is a digital micromirror device (DMD). A bonded wafer is made up of two or more layers of any material that adhere to each other. In a MEMS device, a bonded wafer may include a window layer or glass layer on an interposer layer. The interposer layer is on an integrated circuit (IC) layer that includes IC components (e.g., complementary metal oxide transistor circuitry (CMOS) circuitry). The bonded wafer may include a plurality of ICs. During and/or after fabrication of the bonded wafer, the bonded wafer may be cut to break the plurality of ICs into individual components. In some examples, the IC layer includes portions of the wafer structured to be removed during fabrication to expose bond pads. The bond pads are exposed so that a user or manufacturer can connect the bond pad to one or more other devices (e.g., via wires, etches, printed circuit boards (PCBs), etc.).

To expose and/or otherwise provide access to the bond pads on the IC layer of a bonded wafer, there may be a gap between the layer (e.g., the interposer layer) and a portion of the IC layer that includes the bond pads. Additionally, there are gaps and/or open spaces in the glass layer and/or interposer layer to provide weak points for removing portions of the glass layer and/or interposer layer that can be broken off. In this manner, after the bonded wafer is cut, a pressure and/or force can be applied to the portions of the layers above the bond pad. Because the cavities create weak points in the corresponding layers, applying the pressure and/or force will cause the portions layers above the bond pads to break off, thereby exposing the bond pads beneath. However, the removal of sections of the layers above the IC layer can be problematic. For example, the removal of sections of the layers can cause flared edges, chipped edges, and/or IC damage due to the debris and/or overburden caused by the cutting and/or force application processes. For example, cutting the bonded wafer generates swarf (e.g., the debris or waste resulting from the cutting process). If the swarf comes into contact with the IC layer, the swarf may scratch or otherwise damage the surface of the IC layer. In another example, when the portion of the layers above the IC layer is broken off (e.g., to expose the bond pads), the broken off portion may scratch and/or otherwise cause damage to the IC layer. Accordingly, removing bonded wafer material above the bond pads may result in device damage and, accordingly, manufacturing yield loss.

Examples disclosed herein provide structure to improve yield of IC components by reducing the risks of damage caused by the cutting and/or layer removal process. As part of the window assembly fabrication, a metal ring (also referred to as a bond ring) is plated on an IC (e.g., a CMOS) and a Window Assembly (WA) surface. The bond ring creates a bond between the CMOS and WA and creates a hermetic seal for the cavity. Examples disclosed herein extend the bond ring beyond the geometry of the window cavity and wrap it around the bond pad edge. The extension of the bond ring forms a temporary seal (also referred to as a swarf seal, metal seal, barrier, swarf barrier, metal barrier) between the IC layer and the WA surface. The swarf barrier is designed to overlap a protective resist (e.g., a photoresist and/or dielectric material) on the IC. The protective resist is removed during fabrication, thereby leaving the swarf barrier with a lifted, unsupported edge. The edge forms a deformable sealing surface (also referred to as a crushable gasket). The deformable sealing surface adds tolerance to spacing between IC and WA during the bonding process.

The swarf barrier disclosed herein prevents and/or decreases the probability of the swarf damaging the IC during the cutting process because the deformable sealing surface blocks the swarf from entering the bond pad region. Additionally, the swarf barrier disclosed herein acts as a standoff to the overburden caused by the breaking off of portions of the interposer and/or glass layers to expose the bond pads of the IC layer, thereby preventing the edge of the removed portions from striking and damaging the IC layer.

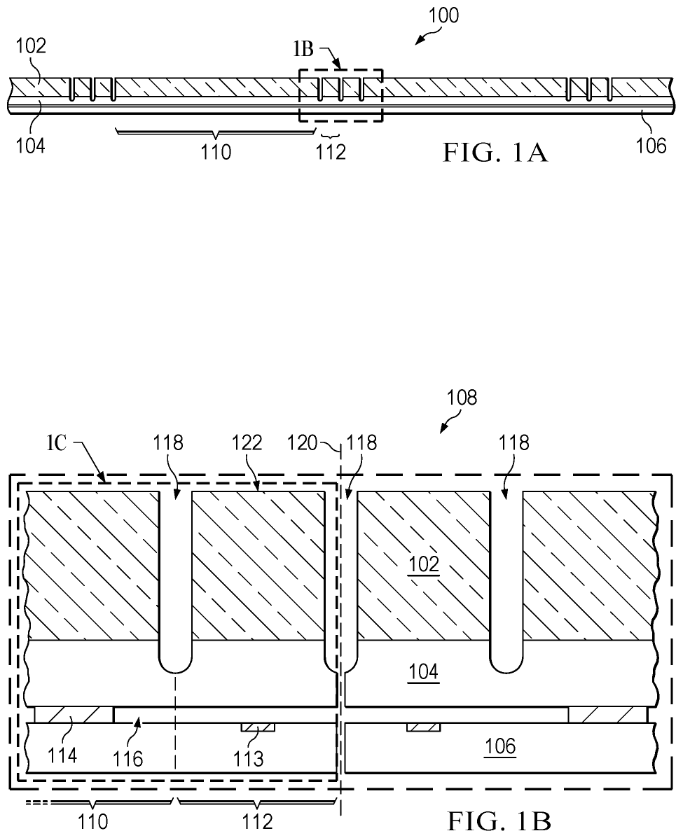

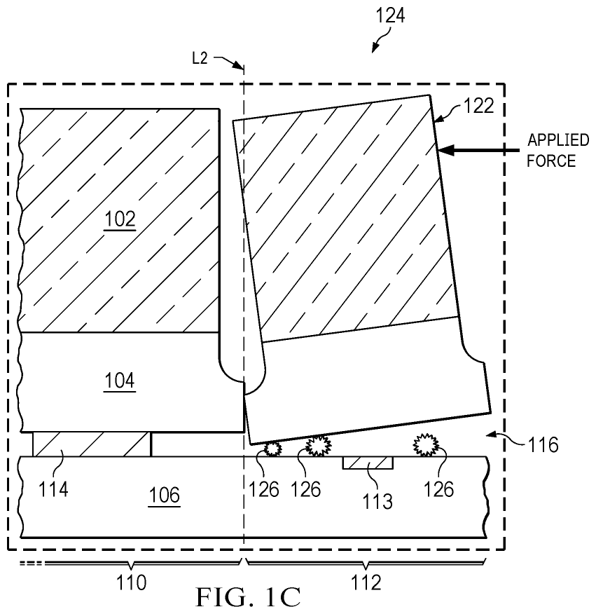

FIGS. 1A-1C include a schematic diagram of an example bonded wafer 100 that reflects the risks of damage caused by the cutting process for some bonded waters. The example bonded wafer 100 includes an example glass layer (also referred to as a glass window or window layer) 102, an example silicon interposer layer (also referred to as an interposer layer) 104, and an example IC layer 106 (also referred to as a semiconductor layer). FIGS. 1A-1C further include an example zoomed in view 108 of the bonded wafer 100. The view 108 includes an example cavity area 110 of the IC layer 106, an example bond pad area 112 of the IC layer 106, an example bond pad 113, an example bond ring 114, an example gap area 116, example gaps 118, an example cut line 120 (e.g., also referred to as a scribe line, a cut street, a scribe street, etc.), and an example break portion 122 (e.g., a portion to be removed to expose the bond pad 133). FIGS. 1A-1C further include an example zoomed in view 124 of the view 108 from the bonded wafer 100. The view 124 includes the bond ring 114, the gap area 116, the break portion 122, and example swarf 126.

The bonded wafer 100 of FIGS. 1A-1C includes three layers. The first layer is the example glass layer 102. The glass layer 102 is above (e.g., on top of) the second layer formed by the interposer layer 104. The interposer layer 104 is above the third layer formed by the IC layer 106. The glass layer 102 may be used as a carrier substrate in the production of the bonded wafer 100 to allow the IC layer 106 to be handled safely. The interposer layer isolates the IC components in the IC layer 106 from stresses that may be exerted on the bonded wafer 100. For example, the IC layer 106 may include CMOS circuitry, MEMS circuitry, deformable micromirror device (DMD) circuitry, etc. While three layers are shown in the example of FIGS. 1A-1C, the bonded wafer 100 may include any number and/or type of layers.

The view 108 of FIGS. 1A-1C illustrates a portion and/or edge of a particular IC component of the IC layer 106. The IC layer 106 includes the cavity area 110 and the bond pad area 112. The cavity area 110 corresponds to the IC components and/or circuitry and the bond pad area 112 is where the bond pad 113 is located. The bond pad 113 allow external components to be connected to the IC components in the cavity area 110. Above the cavity area 110 is a bond ring 114 that bonds the interposer layer 104 to the IC layer 106. Above, the bond pad area 112 is a gap area 116 (e.g., corresponding to a predefined length) where there is a gap between the interposer layer 104 and the IC layer 106. The gaps 118 illustrate a hollowed out portion of the glass layer 102 and/or interposer layer 104. The gaps 118 are generated by cutting the bonded wafer 100 after the layers have been bonded together. The gaps 118 correspond to weak points where the break portion 122 of the glass layer 102 and/or interposer layer 104 will break off when a force and/or pressure is applied, thereby exposing the bond pad area 112 of the IC layer 106.

However, as shown in the view 124 of FIGS. 1A-1C, when the bonded wafer 100 is cut along the cut line 120 to separate the bonded wafer 100 into individual chips, the swarf 126 (e.g., debris from the cutting process) can enter into the gap area 116 and cause damage to the IC layer 106. Additionally, when the force is applied to the break portion 122 (e.g., to remove a portion of the glass layer 102 and/or interposer layer 104 so that the bond pad area 112 can be exposed), the break portion 122 can come into contact with the bond pad area 112 and cause damage to the bond pad area 112 (e.g., by scrapping, digging, cracking, etc. the bond pad area 112). To prevent the damage caused by the cutting and/or bond pad exposure process, examples disclosed herein extend the bond ring 114 around a perimeter of the bond pad area 112 to provide a swarf barrier that reduces and/or eliminates the risk of (a) the swarf 126 entering the gap area 116 and/or (b) damaged caused by the break portion 122, as further described below.

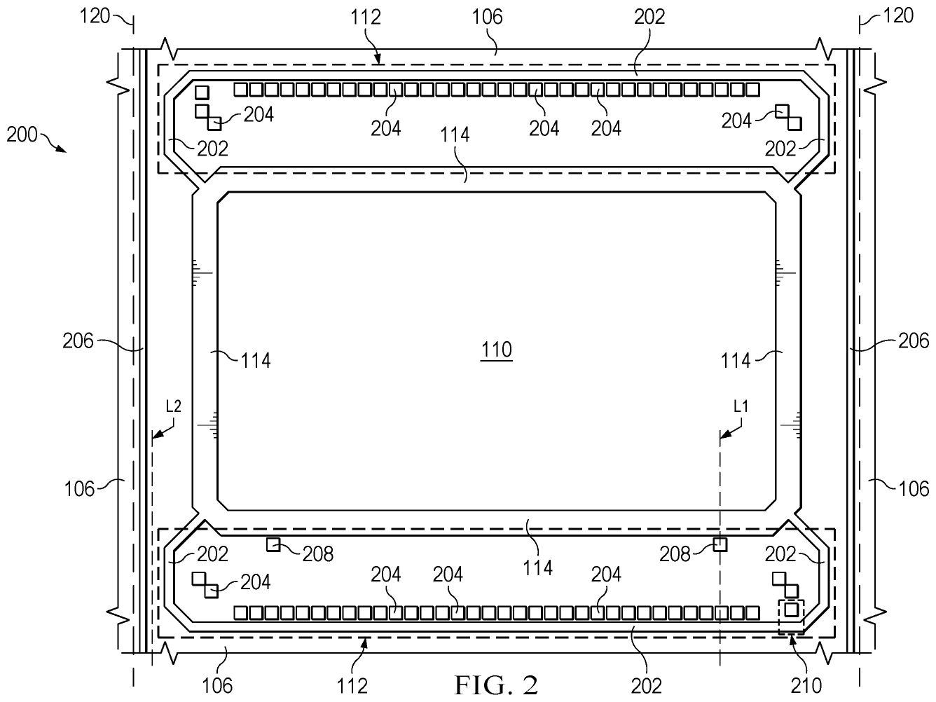

FIG. 2 illustrates a top view of an IC layer 200 including an example swarf barrier 202 to protect the bond pad area 112 of the IC layer 200 in a bonded wafer to eliminate and/or reduce the risks associated with the bonded wafer 100 of FIGS. 1A-1C. FIG. 2 includes the cavity area 110, and the bond pad area 112 of FIGS. 1A-1C. FIG. 2 further includes the example swarf barrier 202, example bond pads 204 (which may include the bond pad 113 of FIGS. 1A-1C), an example scribe seal 206, example metal fingers 208, and an example portion 210.

The bond ring 114 of FIG. 2 is a metal ring around the cavity area 110 that provides a metallic bond between the IC layer 106 and other layers of the bonded wafer (e.g., the interposer layer 104 and/or the glass layer 102 of FIGS. 1A-1C). Additionally, the bond ring 114 helps to seal the IC layer and create a mini environment around the IC components. In some examples, the bond ring 114 is on top of a seed metal. A seed metal is a layer of metal that may facilitate the electroplating of the bond ring 114. The bond ring 114 may be several microns thick and made of gold, nickel, and/or any other metal.

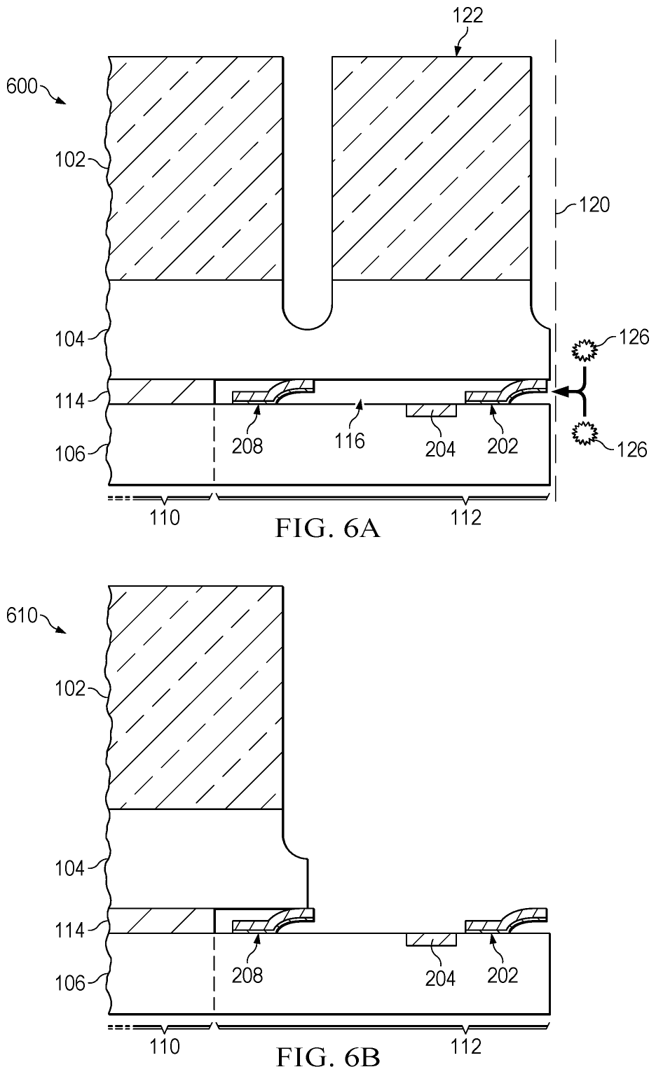

The swarf barrier 202 (also referred to as barrier, seal, metal barrier, metal seal, swarf seal, etc.) of FIG. 2 is an extension of the bond ring 114 around the bond pad area 112 of FIGS. 1A-1C. The swarf barrier 202 protects the bond pads 204 in the bond pad area 112 from swarf generated during the cutting process of the bonded wafer. For example, the swarf barrier 202 is structured to connect the IC layer 106 and the interposer layer 104 to create a seal between the layers 104 (or another layer above the IC layer 106) so that when the cutting process occurs, the swarf generated by the cutting process cannot enter into the bond pad area 112. Accordingly, the swarf barrier 202 protects the bond pads 204 and/or the bond pad area 112 from being damaged by the swarf, as further described below in conjunction with FIG. 6A.

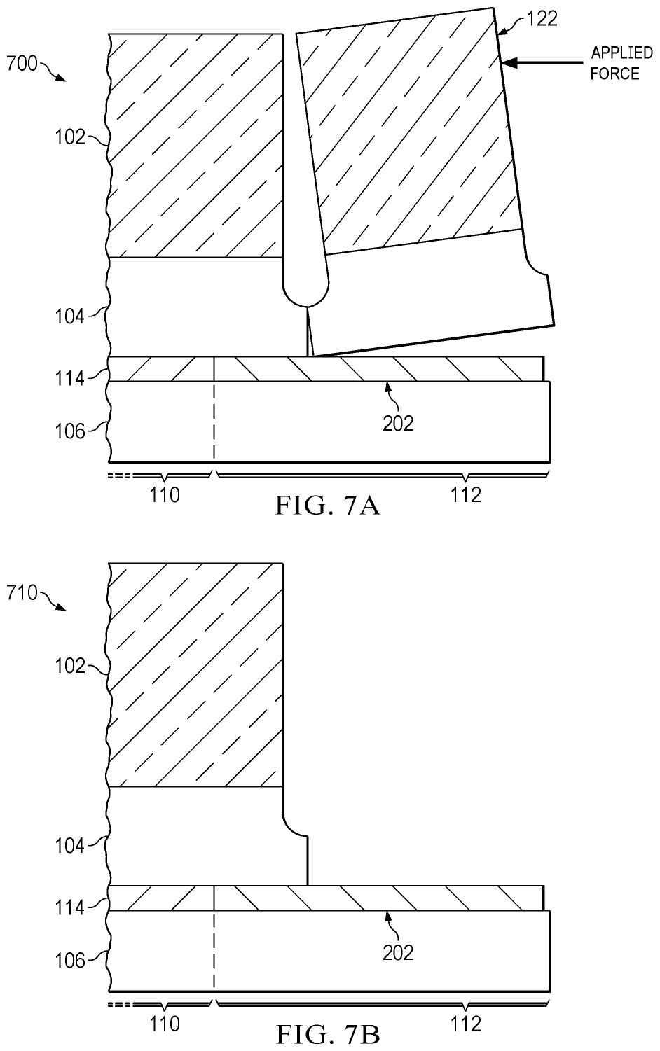

Additionally, in the examples shown, the swarf barrier 202 provides protection from the break portion 122 of above layers (e.g., the interposer layer 104, the glass layer 102, etc.) when the break portion 122 is removed. For example, when force is applied to the break portion 122, because the swarf barrier 202 is elevated above the IC layer 106, the swarf barrier 202 prevents the break portion 122 from coming into contact with (e.g., scratching, chipping, scrapping, etc.) the bond pads 204 and/or the bond pad area 112, as further described below in conjunction with FIG. 7A. The swarf barrier 202 may be made of the same material as the bond ring 114 and/or may be made of different material. In some examples, the swarf barrier 202 is made from a soft and/or malleable metal (e.g., gold, nickel, silver, etc.) to function as a crushable gasket. For example, the swarf barrier 202 is soft enough so that when the interposer layer 104 is pressed toward the IC layer 106, the swarf barrier 202 will compress, bend, etc. slightly downward to ensure that the swarf barrier 202 properly seals a gap area (e.g., corresponding to a length and/or height of the swarf barrier 202) between the IC layer 106 and the interposer layer 104 above the bond pad area 112 to prevent swarf from causing damage to the bond pad area 112.

The scribe seal 206 of FIG. 2 is a metal and/or dielectric layer on top of the IC layer 106 and below (e.g., beneath, on bottom of, etc.) the swarf barrier 202. The scribe seal 206 surrounds (e.g., encloses) the active region of the IC layer (e.g., the IC components and/or bond pads 204). The scribe seal 206 prevents and/or otherwise reduces the risk of cracks and/or crack migration caused by the cutting process. The scribe seal 206 is located near the cut lines 120. The cut lines 120 correspond to where the wafer is cut to separate the wafer into individual components. Because the scribe seal 206 surrounds an IC component, the scribe seal 206 will surround the bond pad area 112 on at least three sides.

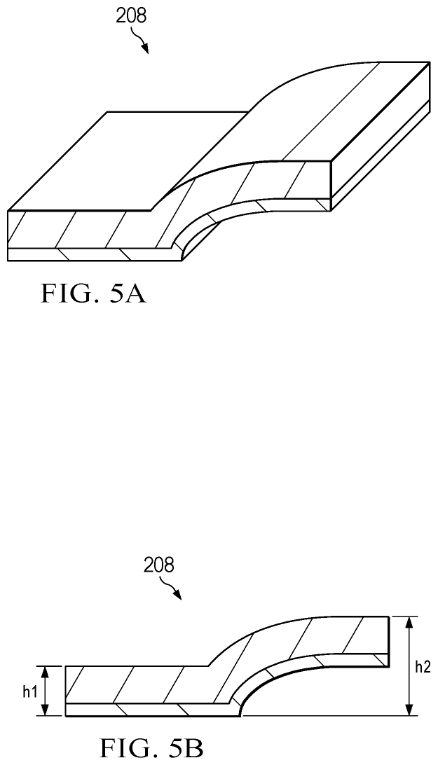

The metal fingers 208 of FIG. 2 provide additional protection against the break portion 122 from causing damage to the bond pad area 112 when force is applied to remove the break portion 122. For example, the metal fingers 208 are located between the IC layer 106 and the interposer layer 104 so that when the interposer layer 104 is removed, the metal fingers 208 prevent the interposer layer 104 from scraping the IC layer 106. In some examples, the metal fingers 208 are standalone components, as shown in FIGS. 5A and 5B. In some examples, the metal fingers 208 extend and/or are otherwise connect to one or more portions of the bond ring 114. An example metal finger is further described below in conjunction with FIGS. 5A and 5B.

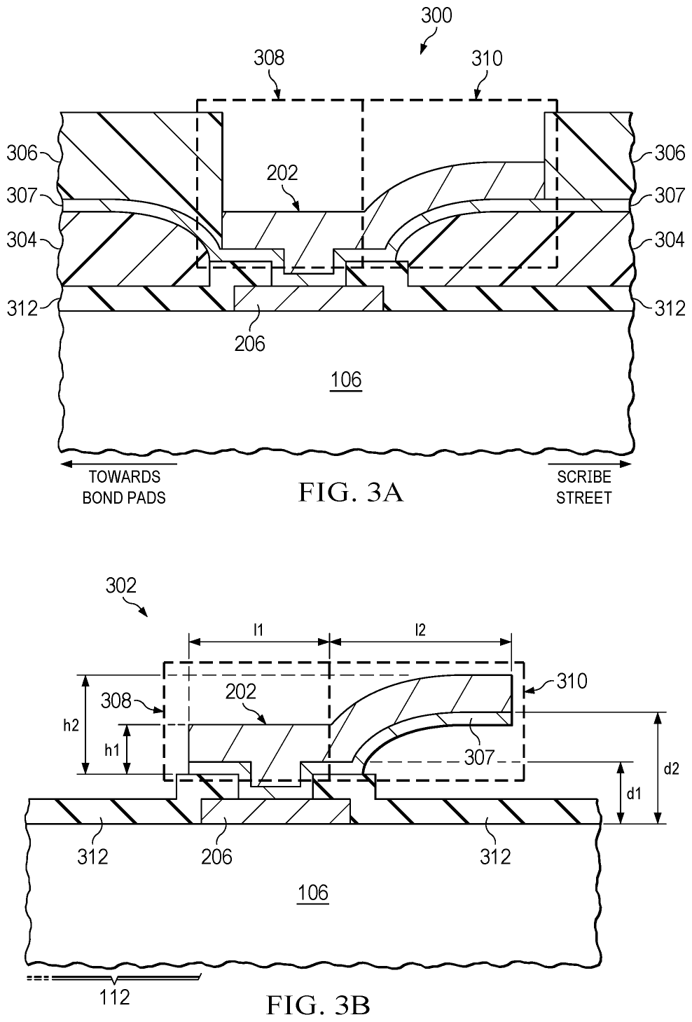

FIGS. 3A and 3B illustrate two cross-sectional views of the swarf barrier 202 of FIG. 2 along line L1 of FIG. 2 (e.g., corresponding to view 1). The first cross-sectional view 300 corresponds to a pre-undercut view and the second cross-sectional view 302 corresponds to a post-undercut view. FIGS. 3A-3B include the IC layer 106, the swarf barrier 202, and the scribe seal 206 of FIG. 2. FIG. 3A further includes an example protect resist 304, an example photoresist 306, an example seed metal 307, and an example protective overcoat layer 312. As shown in FIGS. 3A-3B, the swarf barrier 202 includes a first portion 308 and a second portion 310.

The first cross-sectional view 300 of FIG. 3A illustrates the cross-sectional view of the swarf barrier 202 during manufacturing of a bonded wafer prior to the cutting of the bonded wafer into individual components. The swarf barrier 202 is located above the scribe seal 206 and the protective overcoat layer 312. The protective overcoat layer 312 may include a silicon dioxide (SiO₂) outer surface with layers of titanium dioxide (TiO₂) or Titanium Nitride (TiₓN_{y}) underneath. The portion of the view 300 to the left of the scribe seal 206 corresponds to the bond pad area 112 of the IC layer 106 of FIG. 2. The portion of the view 300 to the right of the scribe seal 206 corresponds to the cut line 120 (e.g., where the wafer is cut to separate the wafer into individual IC components). On the portion toward the bond pads 204, the protect resist 304 is a layer above the IC layer 106 and the protective overcoat layer 312. The protect resist 304 (also known as a photoresist) is a dielectric layer that coats the IC layer 106 and provides a foundation for the structure that will be fabricated. Before the layers of the wafer are bonded, the protect resist 304 is removed using a downstream asher. On top of the protect resist 304 is the seed metal 307. The seed metal 307 may be any type(s) of metal and/or alloy (e.g., titanium-copper, nickel, nickel-tungsten, titanium-tungsten, gold, etc.). The seed metal 307 is applied using a physical wafer disposition technique. The seed metal 307 facilitates the electroplating of layers above the seed metal 307 to prevent electromigration of diffusion of metal during manufacturing on other parts of the wafer. On the portion towards the cut line 120, the protect resist 304 is layered above the IC layer 106. The photoresist 306 forms the platting pattern of the swarf barrier 202. The photoresist 306 may be made of the same or a similar material as the protect resist 304. The swarf barrier 202 is a raised cantilevered structure. Accordingly, the first portion 308 of the swarf barrier 202 is flat and structured above the scribe seal 206 and the second portion 310 is raised above the protect resist 304. At the end of the cantilevered portion of the swarf barrier 202 is the seed metal 307 layered on top of the protect resist 304.

During the plating process, the protect resist 304 is applied on top of the IC layer 106. For example, the protect resist 304 may be patterned before the seed metal 307 is deposited. After applying the protect resist 304, the seed metal 307 is deposited on top of the protect resist 304 and/or the portions of the IC layer 106 that do not have the protective resist 304 above the IC layer 106. After the seed metal 307 is deposited, the photoresist 306 is added above portions of the IC layer 106 to form a plate pattern for the swarf barrier 202. For example, the photoresist 306 is patterned before the plating process generating the swarf barrier 202. After the photoresist 306 is applied to define the plate pattern, plating is performed using the seed metal 307 as a contact to generate the swarf barrier 202. After the swarf barrier 202 is generated, the photoresist 306 defining the plate pattern is removed and the exposed seed metal 307 (e.g., the seed metal 307 outside of the region between the swarf barrier 202 and the IC layer 106) is removed. After the platting sequence, the protect resist 304 is removed during the undercut process.

FIG. 3B illustrates the swarf barrier 202 after, the photoresist 306 and a portion of the seed metal 307 of FIG. 3A are removed (e.g., etched away) and after the protect resist 304 is removed during the undercutting process. As described above, the swarf barrier 202 is made using a metal. In some examples, the swarf barrier 202 is made using the same or a similar metal as the bond ring 114. In some examples, the swarf barrier 202 is made from a soft and/or malleable metal (e.g., gold, nickel, silver, etc.) to allow the second portion 310 of the swarf barrier 202 to compress when the layers 102, 104, 106 are bonded to form a seal.

The example view 302 illustrates post undercut view after the protect resist 304 and the seed metal 307 have been removed. The second portion 310 is raised so that when the interposer layer 104 is pressed toward the IC layer 106, the second portion 310 can compress, bend, and/or press toward the IC layer 106 to create a seal (e.g., like a crushable gasket). The first portion 308 of the swarf barrier 202 is flat and the second portion 310 is a curved portion. The second portion 310 extends up from the first portion 308 so that when the layers are bonded, the second portion 310 will create a seal with the interposer layer 104 to prevent swarf from entering into the gap area 116 above the bond pad area 112 of FIGS. 1 and/or 2. The second portion 310 also can protect the bond pad area 112 from damage when the break portion 122 of the interposer layer 104 and/or glass layer 102 is/are removed by preventing the break portion 122 from coming into contact with the IC layer 106.

In some examples, the thickness of the swarf barrier 202 is 2.5 microns (um). However, the thickness of the swarf barrier 202 may be thicker or thinner to increase or decrease the movement of the swarf barrier 202 when the other layers are bonded to the IC layer 106 to create a seal. The swarf barrier 202 of FIGS. 3A-3B is illustrated the second portion as curving up from a first height (h1) of the first portion 308 to a second height (h2) of the second portion 310. In some examples, the first height corresponds to the thickness (e.g., 2.5 um) and the second height can be around 6-7 um. However, the second height may correspond to the height of the bond ring 114 and/or may be higher or lower depending on the desired height of the gap area 116 over the bond pad area 112.

Additionally, the first portion 308 is located a first distance (d1) away from the first layer and the second portion 310 is located a second, longer distance (d2) away from the first layer. The first distance corresponds to the thickness of the scribe seal 205, the protective overcoat 312, and the seed metal 307 because the scribe seal 205, the protective overcoat 312, and the seed metal 307 are located between the swarf barrier 202 and the IC layer 106. In some examples, the first distance is less than 1 micron. However, the first distance may be any distance corresponding to the sum of the thicknesses of the scribe seal 205, the protective overcoat 312, and the seed metal 307. The second distance may be 3.5 to 4 um. However, the second distance may correspond to the height of the bond ring 114 and/or may be increased or decreased depending on the desired height of the gap area 116 over the bond pad area 112.

The first portion 308 of the swarf barrier 202 corresponds to a first length (11) and the second portion 310 of the swarf barrier 202 corresponds to a second length (12). In some examples, the first length is the same as the second length. In some examples, the first length is longer or shorter than the second length. For example, the first length may be 35 microns while the second length may be 15 microns.

In the examples of FIGS. 3A and 3B, the second portion 310 of the swarf barrier 202 is a curve shape up from the first height to the second height. However, the swarf barrier 202 may be structured to include a step-up portion, an angled portion, only a rectangular portion (e.g., a swarf barrier 202 that only includes the first portion 308 and does not raise up to the second portion 310), and/or in any type of structure capable of blocking swarf and/or preventing damage caused removal or portions of other layers.

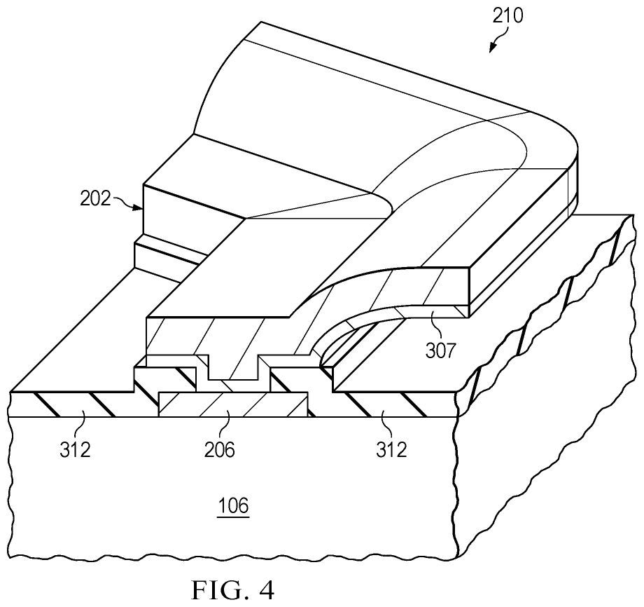

FIG. 4 illustrates an angled cross-section view of the portion 210 of the swarf barrier 202 of FIG. 2. FIG. 4 includes the IC layer 106, the swarf barrier 202, and the scribe seal 206 of FIG. 2 and the protective overcoat layer 312 of FIG. 3. As shown in FIG. 4, the swarf barrier 202 follows the scribe seal 206 to protect from swarf at each angle where the IC layer 106 is cut during the cutting process. For example, because the scribe seal 206 corresponds to the cut line 120 where the IC layer 106 is to be cut, the swarf barrier 202 is located on the scribe seal 206 to protect the bond pad area 112 from the swarf.

FIGS. 5A and 5B illustrate the example metal finger 208 of FIG. 2. FIG. 5A is a three-dimensional view and FIG. 5B is an orthogonal view. The example metal finger 208 corresponds to the same structure as the swarf barrier 202 of FIGS. 2-4. However, the metal finger 208 is not located above the scribe seal 206. Instead, the metal finger 208 can be placed in any location within the bond pad area 112 to provide additional support. Like the swarf barrier 202, the metal finger 208 includes a first portion that is flat and a second portion that is raised so that when the interposer layer 104 is pressed toward the IC layer 106, the second portion can bend and/or press toward the IC layer 106 to create a seal (e.g., like a crushable gasket). The geometries of the metal finger 208 (e.g., thickness, heights, lengths, distances, shape) may match the geometries of the swarf barrier 202 or may be different than the geometries of the swarf barrier 202. For example, because the metal finger 208 is protecting against damage from the break off portion 122 and not damage from swarf, the second height of the metal finger 208 may be lower than the second height of the swarf barrier 202 and the thickness may be larger to allow the swarf barrier 202 to bend to create a seal with the interposer layer 104 while the metal finger 208 will not bend to prevent the break portion 122 from touching the IC layer 106. In the example of FIG. 5A, the width of the metal finger 208 is 32 micron. However, the width of the metal finger 208 can vary based on how much protection from the break portion 122 is desired. Additionally, the metal finger 208 can provide protection from the break portion 122. For example, the metal finger 208 can prevent the break portion 122 from touching the IC layer 106 and causing damage. Although the metal finger 208 illustrates the second portion curving up from a first height (h1) of the first portion to a second height (h2) of the second portion, the metal finger 208 may be structured as a step-up, a line (e.g., sloped at some degree from the first portion), as a rectangle (e.g., a metal finger 208 that only includes the first portion and does not raise up to the second portion), and/or in any other structure.

FIGS. 6A and 6B illustrates two cross-sectional views 600, 610 of a bonded wafer along line L1 of FIG. 2 (e.g., corresponding to view 1). FIGS. 6A and 6B includes views of the swarf barrier 202 of FIG. 2 before and after removal of the break portion 122 of FIGS. 1A-1C. The pre-removal view 600 of the bonded wafer includes the glass layer 102, the interposer layer 104, the IC layer 106, the bond ring 114, the cut line 120, the break portion 122, and the swarf 126 of FIGS. 1 and/or 2. The pre-removal view 600 of the bonded wafer further includes the swarf barrier 202, the bond pad 204, and the metal finger 208 of FIG. 2. The post-removal view 610 of the bonded wafer includes the glass layer 102, the interposer layer 104, the IC layer 106, and the bond ring 114 of FIGS. 1 and/or 2. The post-removal view 610 of the bonded wafer further includes the swarf barrier 202, the bond pad 204, and the metal finger 208 of FIG. 2.

During the fabrication of the bonded wafer, the glass layer 102, the interposer layer 104, and the IC layer 106 are pressed together to bond the layers 102, 104, 106. As described above, the swarf barrier 202 and/or the metal finger 208 is structured to act as a crushable gasket to compress, press, bend, etc. to create a seal between the interposer layer 104 and the IC layer 106. In this manner, as shown in the pre-removal view 600, during the cutting process along the cut line 120, the swarf 126 will not enter into the empty region and/or gap between the interposer layer 104 and the IC layer 106. Accordingly, the bond pad 204 is protected from potential damage that could be caused by the swarf 126 during and/or after the cutting process.

As described above, after the bonded wafer is cut along the cut lines (e.g., including the cut line 120) to separate the bonded wafer into individual components, a force is applied to the break portion 122 of the glass layer 102 and the interposer 104. The force applied to the break portion 122 causes the break portion 122 to break off, thereby exposing the bond pad 204, as shown in the post removal view 610. In this manner, the bond pad 204 can be accessed to allow a user or device to apply a wire, etch, etc. to the bond pad 204. When the break portion 122 breaks off due to the applied force, the swarf barrier 202 and/or the metal finger 208 prevents the break portion 122 from scrapping, chipping, or otherwise coming into contact with the IC layer 106. Accordingly, the swarf barrier 202 and/or the metal finger 208 protect the IC layer 106 from damage during the cutting process and during the break portion removal process. In FIGS. 6A and 6B, the swarf barrier 202 and the metal finger 208 correspond to a step-up structure. However, the swarf barrier 202 and/or the metal finger 208 may correspond to a curve (e.g., as shown in FIGS. 3-5), a line (e.g., sloped at some degree from the first portion), a rectangle, and/or in any other structure that can ack as a crushable gasket to provide a seal and/or protect the IC layer 106 during the cutting process and/or break portion removal process.

FIGS. 7A and 7B illustrates two cross-sectional views 700, 710 of a bonded wafer along line L2 of FIG. 2 (e.g., corresponding to view 2). FIGS. 7A and 7B includes views of the swarf barrier 202 of FIG. 2 during and after removal of the break portion 122 of FIGS. 1A-1C. The during-removal view 700 of the bonded wafer includes the glass layer 102, the interposer layer 104, the IC layer 106, the bond ring 114, and the break portion 122 of FIGS. 1 and/or 2. The during-removal view 700 of the bonded wafer further includes the swarf barrier 202 of FIG. 2. The post-removal view 710 of the bonded wafer includes the glass layer 102, the interposer layer 104, the IC layer 106, and the bond ring 114 of FIGS. 1 and/or 2. The post-removal view 710 of the bonded wafer further includes the swarf barrier 202 of FIG. 2.

As described above, after the bonded wafer is cut along the cut lines (e.g., including the cut line 120) to separate the bonded wafer into individual components, a force is applied to the break portion 122 of the glass layer 102 and the interposer 104. The force applied to the break portion 122 causes the break portion 122 to break off, thereby exposing the bond pad 204, as shown in the post removal view 710. In this manner, the bond pad 204 can be accessed to allow a user or device to apply a wire, etch, etc. to the bond pad 204. When the break portion 122 breaks off due to the applied force, the swarf barrier 202 and/or metal fingers 208 (not shown in FIGS. 7A-7B) prevent the break portion 122 from scrapping, chipping, or otherwise coming into contact with the IC layer 106. Accordingly, the swarf barrier 202 and/or the metal finger 208 protect the IC layer 106 from damage during the during the break portion removal process.

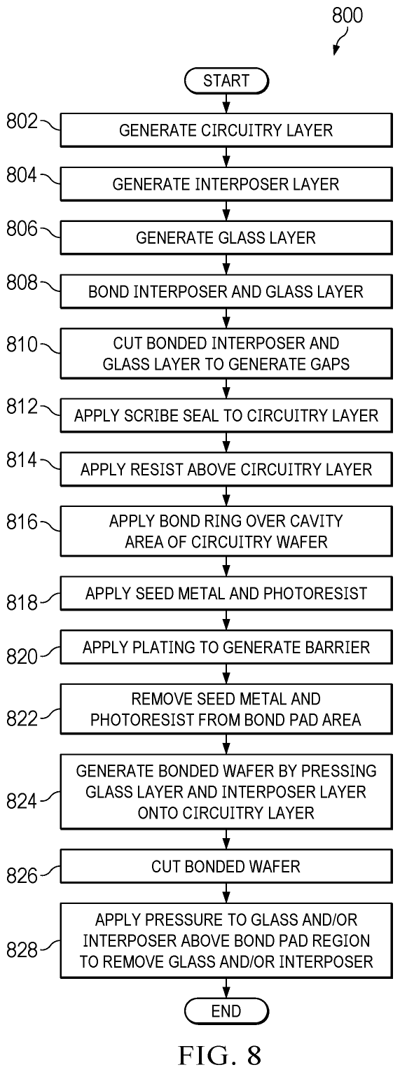

FIG. 8 is an example flowchart 800 representative of method, instructions, and/or functionality of manufacturing/fabrication device to generate a bonded wafer with a swarf barrier and/or metal fingers to prevent damage to an IC layer of the bonded wafer. The example flowchart 800 begins at block 802 when the IC layer 106 is generated. The IC layer 106 is a silicon-based layer that corresponds to circuitry. For example, the IC layer 106 may include CMOS circuitry, MEMS circuitry, DMD circuitry, etc. At block 804, the interposer layer 104 is generated. At block 806, the glass layer 102 is generated.

At block 808, the interposer layer 104 and the glass layer 102 are bonded together. For example, the interposer 104 and the glass layer 102 are bonded using a low temperature fusion bond. A low temperature fusion bond includes putting an oxide coating on the faces of the layers 102, 104, polishing the layers 102, 104 to make the layers flat, making the layers 102, 104 clean, and press the layers 102, 104 together. After being pressed together, the layers 102, 104 are baked (e.g., at 450 degrees Celsius) to bond the layers 102, 104. At block 810, the bonded interposer and glass layers are partially cut to generate the example gaps 118 of FIGS. 1A-1C. the gaps 118 correspond to the edges of the IC components and/or the bond pad regions. As described above, the gaps 118 define the break portion 122 that is removed after the layers are bonded to expose the bond pads 113.

At block 812, the scribe seal 206 of FIG. 2 is formed on the IC layer 106. For example, the scribe seal 206 may be formed as a solid metal barrier that goes down into the surface of the IC layer 106. As described above, the scribe seal 206 is located near the cut lines and surround the individual components of the IC layer 106. The scribe seal 206 is a metal and/or dielectric layer that prevents and/or otherwise reduces the risk of cracks and/or crack migration caused by the cutting process. At block 814, the protect resist 304 of FIG. 3 (e.g., a photoresist layer) is applied to the IC layer 106 by patterning the protect resist 304 to form the pattern of the swarf barrier 202. As described above, the protect resist 304 provides a foundation for the structure that will be fabricated.

At block 816, the bond ring 114 is applied around the cavity area 110 of the IC layer 106. The bond ring 114 allows the IC layer to be bonded to the interposer and glass layer as further described below at block 824. At block 818, the photoresist 306 and the seed metal 307 is applied over the resist. For example, the photoresist 306 is patterned to define the plate pattern of the swarf barrier 202, as described above in conjunction with FIG. 3A.

At block 820, plating is applied to generate the swarf barrier 202 is applied over at least a portion of the scribe seal 206. For example, because of the pattern created by the resists 304, 306, a region corresponding to the pattern defines where current can flow out of the seed metal 307 to plate the metal that creates the swarf barrier 202 onto the surface of the seed metal 307. At least a portion of the swarf barrier 202 will be above the protect resist 304, as shown in FIG. 3A. If the swarf barrier 202 is an extension of the bond ring 114, the bond ring 114 and swarf barrier 202 are positioned together so that the bond ring 114 is surrounds the cavity area 110 and the swarf barrier 202 surrounds the bond pad area 112 on at least three sides (e.g., where the bond ring 114 provide the fourth side surrounding the pond pad area 112). If the swarf barrier 202 and the bond ring 114 are separated, the bond ring 114 and swarf barrier 202 are positioned separately so that the bond ring 114 surrounds the cavity area 110 and the swarf barrier 202 surrounds the bond pad area 112 on at least three sides. For example, the swarf barrier 202 may come into contact with the bond ring 114 so that the swarf barrier 202 surrounds the bond pad area 112 on three sides the bond ring 114 provides the fourth side surrounding the bond pad area 112. In some examples, the swarf barrier 202 may surround the bond ring 114 on all four sides. Additionally, at block 820, the metal fingers 208 may be plated and/or placed above and/or attached to the IC layer 106 at one or more locations.

At block 822, the seed metal 307 and the resist 304 is removed from the bond pad area. For example, the seed metal 307 and/or resist 304 can be etched away. For example, the seed metal 307 and/or the resist 304 can be etched away using a wet etch (e.g., using two different chemistries) and/or dry etch. At block 824, a bonded wafer is generated by pressing the glass layer 102 and interposer layer 104 onto the IC layer 106. For example, the glass and interposer bonded layer is pressed to the IC layer 106 and a temperature is applied to melt indium or other material, which bonds the IC layer 106 to the glass and interposer bonded layer. The indium may be included in the bond ring 114 and/or layered on top of the bond ring 114. As described above, the swarf barrier 202 and the metal fingers 208 are structured to function as a crushable gasket. Accordingly, pressing the glass layer 102 and the interposer layer 104 into the IC layer 106 causes the swarf barrier 202 and/or metal fingers 208 to compress, press, bend, etc. to form a seal between the interposer layer 104 and the IC layer 106 to protect the bond pad area 112 of the IC layer 106 from damage caused by swarf and/or break portion removal.

At block 826, the bonded wafer is cut along scribe lines to separate the bonded wafer into individual components. At block 828, force and/or pressure is applied to the break portions (e.g., the break portion 122 of FIGS. 1, 6A, and 7A) of the glass layer 102 and the interposer layer 104 above the bond pad region to remove the break portion 122. As described above, the break portion 122 is removed so that the bond pads 204 in the bond pad area 112 can be exposed. In this manner, a user and/or manufacturer can attach a wire or etch to the IC component to implement the IC component.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is further away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

In this description, the term “and/or” (when used in a form such as A, B and/or C) refers to any combination or subset of A, B, C, such as: (a) A alone; (b) B alone; (c) C alone; (d) A with B; (e) A with C; (f) B with C; and (g) A with B and with C. Also, as used herein, the phrase “at least one of A or B” (or “at least one of A and B”) refers to implementations including any of: (a) at least one A; (b) at least one B; and (c) at least one A and at least one B.

Example methods, apparatus and articles of manufacture described herein improve shared pins in ICs by facilitating the use of the share pin as analog or digital in regular mode, DFT mode, and/or boundary scan mode while reducing and/or eliminating leakage current during the boundary scan and/or avoiding damage to an input buffer during the DFT mode.

The term “couple” is used throughout the specification. The term may cover connections, communications, or signal paths that enable a functional relationship consistent with this description. For example, if device A provides a signal to control device B to perform an action, in a first example device A is coupled to device B, or in a second example device A is coupled to device B through intervening component C if intervening component C does not substantially alter the functional relationship between device A and device B such that device B is controlled by device A via the control signal provided by device A.

Numerical identifiers such as “first”, “second”, “third”, etc. are used merely to distinguish between elements of substantially the same type in terms of structure and/or function. These identifiers, as used in the detailed description, do not necessarily align with those used in the claims.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a metal-oxide-silicon FET (MOSFET) (such as an n-channel MOSFET, nMOSFET, or a p-channel MOSFET, pMOSFET), a bipolar junction transistor (BJT—e.g. NPN or PNP), insulated gate bipolar transistors (IGBTs), and/or junction field effect transistor (JFET) may be used in place of or in conjunction with the devices disclosed herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN) or a gallium arsenide substrate (GaAs).

Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

Modifications are possible in the described embodiments, and other embodiments are possible, within the scope of the claims.

What is claimed is:

1. An apparatus comprising:
a semiconductor device layer including a bond pad area, a bond pad on the semiconductor device layer in the bond pad area;
a scribe seal on the semiconductor device layer, the scribe seal surrounding the bond pad on at least three sides; and
a swarf barrier on the scribe seal, the swarf barrier including:
a first portion a first distance from the semiconductor device layer; and
a second portion a second distance from the semiconductor device layer, the second distance being larger than the first distance.

2. The apparatus of claim 1, wherein the second portion is structured to contact a second layer on top of the semiconductor device layer.

3. The apparatus of claim 1, wherein the second portion of the swarf barrier includes at least one of a curved portion, an angled portion, or a step-up portion.

4. The apparatus of claim 1, further including a bond ring on the semiconductor device layer, the swarf barrier connected to the bond ring.

5. A microelectromechanical system (MEMS) device comprising:
a glass layer;
an interposer layer in contact with the glass layer;
a bond ring;
an integrated circuit (IC) layer coupled to the interposer layer by the bond ring, the IC layer including a first area and a second area, the glass layer, and the interposer layer over the IC layer;
and
a swarf barrier on the second area of the IC layer, the swarf barrier having a flat portion and a curved portion.

6. The MEMS device of claim 5, wherein the IC layer includes a scribe seal that encloses the first area of the IC layer and the second area of the IC layer.

7. The MEMS device of claim 6, wherein the swarf barrier is on top of a portion of the scribe seal that corresponds to the second area.

8. The MEMS device of claim 5, wherein the bond surrounds the first area of the IC layer, the bond ring connected to the swarf barrier.

9. The MEMS device of claim 8, wherein the swarf barrier is made of a same material as the bond ring.

10. The MEMS device of claim 5, further including a metal finger on top of the IC layer.

11. The MEMS device of claim 10, wherein the metal finger is configured to come into contact with a portion of the interposer layer prior to removal of the portion of the interposer layer.

12. The MEMS device of claim 5, wherein:
the first area includes the glass layer and the interposer layer over the first area; and the second area does not include the glass layer and the interposer layer over the second area.

13. An apparatus comprising:
a first layer;
a bond pad on the first layer;
a second layer;
a bond ring coupling the first layer and the second layer, a cavity between the first layer and the second layer at least partially surrounded by the bond ring, the bond pad outside the cavity;
a scribe seal on the first layer; and
a swarf barrier on the scribe seal, the swarf barrier surrounding the bond pad on at least three sides.

14. The apparatus of claim 13, wherein:
the second layer is at least one of an interposer layer or a glass layer; and
the first layer is an integrated circuit layer.

15. The apparatus of claim 13, wherein the swarf barrier is configured to prevent the first layer from contacting the second layer when a portion of the first layer is removed.

16. The apparatus of claim 15, wherein the swarf barrier includes:
a first portion located a first distance away from the first layer; and
a second portion located a second distance away from the first layer, the second distance being larger than the first distance, the second portion structured to contact the first layer, the second portion structured to move to a third distance away from the first layer when the portion of the first layer is removed, the third distance being shorter than the second distance.

17. The apparatus of claim 13, wherein the swarf barrier is to prevent swarf from damaging the first layer when the first layer is cut.

18. The apparatus of claim 13, further including a metal finger configure to prevent the first layer from contacting the second layer when a portion of the first layer is removed.
